(19) United States
(12) Patent Application Publication
(10) Pub. No.: US 2014/0124738 A1
(43) Pub. Date: May 8, 2014

(54) HIGH TEMPERATURE SUPERFLUIDITY SYSTEM

(71) Applicants: Alexander R. HAMILTON, Killarney Heights (AU); Andrea PERALI, Camerino (MC) (IT); David NEILSON, Camerino (MC) (IT)

(72) Inventors: Alexander R. HAMILTON, Killarney Heights (AU); Andrea PERALI, Camerino (MC) (IT); David NEILSON, Camerino (MC) (IT)

(21) Appl. No.: 14/073,938

(22) Filed: Nov. 7, 2013

(30) Foreign Application Priority Data
Nov. 7, 2012 (AU) 2012904903

(51) Int. Cl. H01L 29/16

(52) U.S. Cl. CPC H01L 29/1606; B82Y 99/00
USPC 257/29; 977/734

(57) ABSTRACT

A small gap semiconductor system comprises: two parallel semiconductor sheets formed of atomically thin small gap semiconductor, one sheet containing electrons and the other containing holes; a dielectric insulating barrier arranged parallel to and separating the two semiconductor sheets; independent electrical contacts to each of the semiconductor sheets; two dielectric layers above and below the two semiconductor sheets respectively; and two conducting gates sandwiching the two semiconductor sheets and separated from the respective semiconductor sheets by the respective dielectric layers.

### RELATED APPLICATION

The present application claims under 35 USC §119 the benefit of the earlier filing date of Australian Provisional Patent Application No. 2012904903 filed 7 Nov. 2012, which is incorporated by reference in its entirety.

### TECHNICAL FIELD

The present specification relates to superfluidity and in particular to the observation of high-temperature superfluidity of electron-hole pairs in semiconductors.

### BACKGROUND

An exciton is a bound state of an electron and a hole in a semiconductor. Excitons have been predicted to form a superfluid at low temperatures. Bose-Einstein condensation of excitons with a transition temperature of approximately 1 K has been observed in a double quantum well (DQW) system using gallium arsenide (GaAs). However, the estimated exciton density was much below that needed to observe BCS-type superfluidity. Major obstacles to experimental realization of equilibrium superfluidity in such systems include the following:
(a) in most semiconductors, the electron and hole energy bands are mismatched. For example, in GaAs, not only do the effective masses differ by a factor of five, but the holes have highly non-parabolic energy dispersion and spin-3 characteristics.
(b) The dielectric barrier separating, the two quantum wells needs to be thin enough for the electrons and holes to bind together, because the formation of excitons is exponentially suppressed once the thickness of the barrier exceeds the effective Bohr radius of the exciton (13 nm for GaAs). The large bandgap in GaAs means a bias of 1.5 eV needs to be applied across the barrier. Because of the required thinness of the barrier, this leads to a huge electric field across the barrier and hence leakage between the layers in which the quantum wells are realised.

An alternative system, two graphene monolayers of electrons and holes respectively separated by a dielectric barrier, has recently been proposed to observe exciton superfluidity. This system has some clear advantages over the GaAs system. Graphene is a gapless semiconductor with nearly identical conduction and valence bands, so the mismatch between the electron and hole Fermi surfaces is almost eliminated. In addition, the availability of very thin barriers separating the two monolayers makes the region with strong electron-hole pairing effects easily attainable. A harrier thickness as small as 1 mm has already been demonstrated with a hexagonal boron nitride (hBN) dielectric. The barrier can he made so thin for graphene both because there is no need for a large bias between the electron and hole layers, and also because hBN has a much larger bandgap (approximately 5 eV) than the barrier in GaAs (approximately 0.5 eV), allowing the barrier thickness to be readily reduced without electrical leakage between layers.

However there is a new obstacle with monolayer graphene associated with the linear single-particle energy dispersion, which makes it difficult to access the region of strong interactions. Also, bound excitons do not form because of the massless carriers. The interaction ratio rₛ, defined as the ratio of the average Coulomb interaction energy to the kinetic energy, is a useful measure of the importance of exciton interactions in a semiconductor. Recent theory suggests that exciton superfluid would only occur at measurable temperatures for rₛ>2.3 in graphene monolayers, but monolayer graphene can only have an interaction ratio rₛ of approximately one. Very recent experiments have shown no evidence of superfluidity in a graphene monolayer system with barrier thicknesses as low as 1 nm.

### SUMMARY

The present invention seeks to overcome, or at least mitigate, one or more disadvantages of existing systems for observing exciton superfluids.

In accordance with one aspect of the invention, there is provided a small gap semiconductor system comprising: two parallel semiconductor sheets formed of an atomically thin small gap semiconductor, one sheet containing electrons and the other containing holes; a dielectric insulating barrier arranged parallel to and separating the two semiconductor sheets; independent electrical contacts to each of the semiconductor sheets; two dielectric layers above and below the two semiconductor sheets respectively; and two conducting gates sandwiching the two semiconductor sheets and separated from the respective semiconductor sheets by the respective dielectric layers.

In one implementation, the disclosed semiconductor system comprises a pair of parallel graphene bilayers of electrons and holes respectively, separated by a dielectric insulating barrier of hexagonal boron nitride (hBN) to prevent tunneling between the bilayers. The two bilayers each have separate electrical contacts and a bias voltage can be applied between the contacts. Top and bottom gates are placed above and below the two graphene, bilayers, separated from the bilayers by a dielectric. Biases applied to top and bottom metal gates sandwiching the two bilayers, as well as between the two bilayers, allow independent control over the densities of electrons and holes respectively in the two bilayers, and can adjust the symmetry of the electric field across the two bilayers. By tuning the three biases, a wide range of electron and hole densities can be achieved. The combination of thin barrier, large interaction ratio, and matched hole and electron bands make the disclosed system suitable for inducing and observing superfluidity of excitons at high temperatures, i.e. temperatures above the boiling point of liquid nitrogen (77 Kelvin).

### BRIEF DESCRIPTION OF DRAWINGS

The embodiments of the invention are described hereinafter in relation to one or more drawings, in which:

FIG. 1 is an illustration of a semiconductor system according to one embodiment.

### DETAILED DESCRIPTION

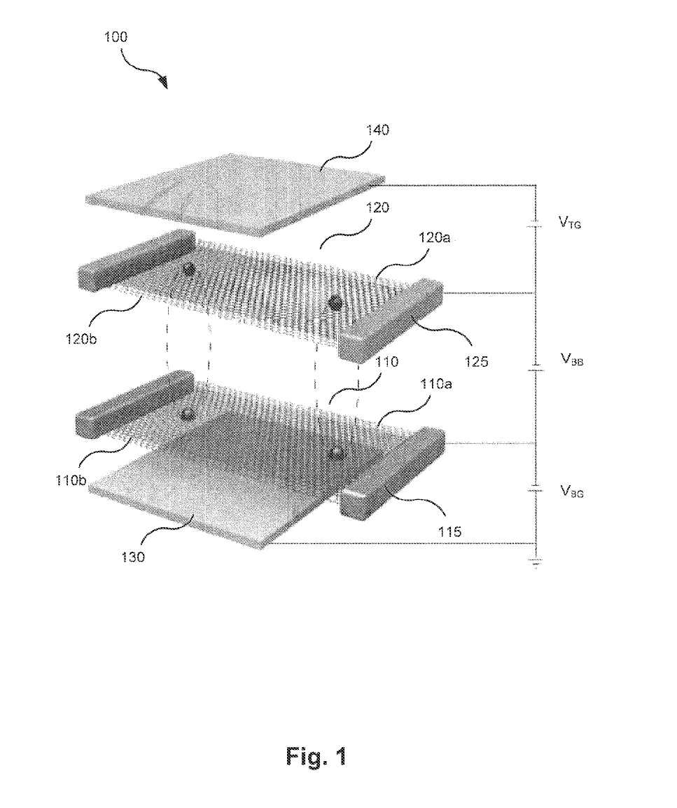

FIG. 1 is an illustration of a semiconductor system 100 according to one embodiment. The system 100 comprises a pair of parallel semiconductor sheets 110, 120 separated by a dielectric insulating harrier (not shown). The lower semiconductor sheet 110 is an electron bilayer comprising two parallel, A-B stacked, closely coupled electron layers 110a and 110b, both atomically thin graphene sheets, with layer separation Dₑ. There is strong electron hopping between the two electron layers 110a and 110b. The upper semiconductor sheet 120 is a hole bilayer comprising two parallel, A-B stacked, closely coupled hole layers 120a and 120b, also of graphene, with layer separation Dₕ equal to the electron layer separation Dₑ. In one implementation, Dₕ=Dₑ=0.37 nm. The dielectric insulating barrier is a sheet of hexagonal boron nitride (hBN) parallel to the two bilayers 110 and 120, of width D_{B} chosen to be substantially greater than the layer separation Dₑ to prevent tunneling between the bilayers 110 and 120.

In other implementations, the dielectric insulating barrier is a sheet formed of another insulating material, such as aluminum oxide, silicon dioxide, or an organic insulator.

The bilayers 110, 120 have separate respective electrical contacts 115, 125, between which a bias voltage V_{BB} may be applied. The two bilayers 110, 120 are sandwiched by two conducting gates 130 and 140, which are insulated from the bilayers by additional dielectric layers (not shown). A bias voltage V_{TG} may be applied between the top gate 140 and the contact 125 of the hole bilayer 120. A bias voltage V_{BG} may be applied between the contact 115 of the electron bilayer 110 and the bottom gate 130. The biases V_{BB}, V_{TG}, and V_{BG} allow independent control over the carrier density in each bilayer, and can adjust the symmetry of the electric field across the two bilayers. By tuning the three biases V_{BB}, V_{TG}, and V_{BG}, a wide range of electron and hole densities can be achieved in the respective bilayers. The values of the biases V_{BB}, V_{TG}, and V_{BG} to achieve particular hole and electron densities depend on the thicknesses of the respective insulating layers. Typically the values of the biases V_{BB}, V_{TG}, and V_{BG} are in the range 0.1 to 100 volts, and V_{TG} and V_{BG} will tend to be smaller than V_{BB}. In one implementation, the density of holes in the hole bilayer 120 is maintained equal to the density of electrons in the electron bilayer 110, both being represented by the carrier density n.

Bilayer graphene has been well characterized and exhibits extremely low levels of disorder. Also, the electron and hole bands are near-perfectly matched. However, in other implementations, other small gap semiconductors that can be manufactured in atomically thin sheets are used to form the semiconductor sheets 110 and 120.

Bilayer graphene mitigates the problems caused by the linear dispersion of monolayer graphene, since over a wide range of carrier densities n, namely 1×10¹¹<n<4×10¹² cm⁻², symmetrically biased graphene bilayers behave as a zero gap semiconductor with a parabolic (quadratic) dispersion around the Fermi level:

$${E}_{\pm } ( k ) = \pm \frac{{ℏ}^{2} {k}^{2}}{2 {m}^{*}} \qquad ( 1 )$$

The effective mass m* is approximately equal to 0.03 to 0.05 times mₑ (the mass of an electron), depending on the carrier density n. With quadratic energy dispersion, as in equation (1), the Fermi energy in the bilayers depends linearly on carrier density n:

$${E}_{F} = \frac{{πℏ}^{2} n}{{g}_{v} {m}^{*}} \qquad ( 2 )$$

so the interaction ratio rₛ depends on carrier density n as follows:

$${r}_{s} = ( \frac{{e}^{2}}{k} ) ( \frac{{g}_{v} {m}^{*}}{{ℏ}^{2}} ) ( \frac{1}{\sqrt{π n}} ) \qquad ( 3 )$$

To experimentally reach large interaction ratio rₛ and the strongly interacting regime in the graphene bilayers, it is enough to decrease the carrier density n with suitable gate voltages V_{BB}, V_{TG}, and V_{BG}. In a graphene monolayer, the minimum carrier density n is restricted by onset of electron puddle formation. Graphene on a hBN substrate shows density fluctuations of approximately 1×10⁹ cm⁻². Uniform densities as low as 1×10¹¹ cm⁻² have been reported in graphene monolayer systems. For graphene bilayers, applying equation (3) at a carrier density n of 1×10¹¹ cm⁻² gives an interaction ratio rₛ of approximately 7, which lies in the strongly interacting region.

For a hBN dielectric, setting the effective mass m* to 0.04 m, and using the reduced mass yields an effective Bohr radius of 11 nm, so a dielectric barrier of thickness D_{B} less than approximately 10 nm ensures strong electron-hole pairing. Barriers as thin as 1 nm have been demonstrated experimentally, so this is readily achievably using existing technology.

Table 1 compares the key physical parameters for three semiconductor-based superfluidity systems in which superfluidity of spatially separated electron-hole bound states has been predicted. For the two graphene systems (monolayer and Mayer), an hBN dielectric barrier is used. Dₑₕ is the separation between the electron and hole layers. For the GaAs double quantum well (DQW) system (third row), the energy dispersion is quadratic but (a) the barriers are wide, i.e. layer separation is approximately twice the Bohr radius, (b) the largest value of interaction ratio rₛ is 2, and (c) the effective Rydberg binding energy R_{y}* is small (the dielectric constant κ is large). These restrictions make it difficult to access the strongly interacting region.

For the monolayer graphene (MLG) system (second row), the harriers can be very thin (1 nm), but the linear energy dispersion keeps the system in the weakly interacting region with interaction ratio rₛ<1. What decisively favors the bilayer graphene (BLG) system (first row) is the accessibility of the strongly interacting region under achievable conditions. This is a result of (a) its near-perfectly matched electron and hole bands, (b) the extremely thin barriers (D_{B} approximately 1 nm) and graphene bilayers (Dₑ=0.37 nm), (c) its significantly larger Rydberg binding energy (17 meV) compared with that of GaAs DQW (4.5 meV), and (d) the ability to time the interaction ratio rₛ to large values (7) and thus access the strongly interacting region.

TABLE 1
Physical parameters for three semiconductor based superfluidity systems.
(* Localised excitons do not form in MLG systems)

| | | Bohr | Rydberg | Layer | Maximum | | |
|---|---|---|---|---|---|---|---|
| | Dielectric | radius | binding | separation | carrier | Dₑₕ/ | Interaction |
| System | constant κ | α₀* | energy R_{y}* | Dₑₕ | spacing r₀ | α₀* | ratio rₛ |
| BLG | 4 | 11 nm | 17 meV | 1 nm | 18 nm | 0.1 | 7 |
| MLG | 4 | * | * | 1 nm | 18 nm | * | 0.5 |
| GaAs | 13 | 13 nm | 4.5 meV | 25 nm | 23 nm | 2 | 2 |
| DQW | | | | | | | |

The energy gap Δ as a function of temperature may be calculated for the graphene bilayer system 100 for various carrier densities n and barrier thicknesses D_{B}. The calculations show a maximum energy gap Δₘₐₓ of as much as 400 K (approximately 34 meV) tor the lowest barrier thickness (2 nm) at an approximate carrier density of n=10×10¹¹ cm⁻², and high maximum energy gap Δₘₐₓ across an order of magnitude range of carrier densities n. Large energy gaps comparable to the Fermi temperature (140 K at n=20×10¹¹ cm⁻²) can lead to dramatic experimental signatures.

The mean-field critical T_{C}^{MF} temperature be calculated as the temperature at which the maximum energy gap Δₘₐₓ extrapolates to zero at each density n and barrier thickness D_{B}. The actual superfluid transition temperature T_{C}, taking into account proliferation of vortices and anti-vortices, is the lower of the mean-field critical temperature T_{C}^{MF} and the Kosterlitz-Thouless temperature, approximated as the Fermi energy E_{F} divided by 8. For barrier thickness D_{B}=2 nm, the superfluid transition temperature T_{C} peaks at 150 K at carrier density n=37×10¹¹ cm⁻², and remains above liquid nitrogen temperatures (77 K) until the carrier density n falls below 20×10¹¹ cm⁻². These densities lie within the quadratic energy band range and are readily accessible experimentally since they arc well above the carrier density where inhomogeneities become significant. The huge control over the superfluid transition temperature T_{C} is highlighted by the large density range, more than an order of magnitude, over which superfluidity can be observed in a graphene bilayer system such as the system 100. This is in marked contrast with high-T_{C} superconductors, where superconductivity manifests itself only in a narrow 30% band of doping centered at optimal doping.

Because of the large energy gap and the high superfluid transition temperature T_{C}, the system 100 is suitable for observing strong experimental signatures of the exciton superfluid therein. Although the excitons are neutral, the ability to make separate electrical contacts to the electron and hole bilayers 110 and 120 allows for spectacular electrical effects. Coulomb drag and inter-layer tunneling measurements should show significant enhancements as the temperature is decreased below the superfluid transition temperature T_{C}, while counterflow measurements can directly probe the excitonic superflow.

The superfluid transition temperature T_{C} in the graphene bilayer system 100 is much higher than in conventional superconductors because the transition is driven by the strong attractive Coulomb interaction between electrons and holes. This contrasts with the weak phonon-mediated attractive interactions of a conventional superconductor that act only between electrons in a narrow energy window centered on the Fermi surface.

The graphene bilayer system 100 is a multi-band system with just one condensate. It is an opposite case to multiband superconductors such as magnesium-diboride where pairing is only within the bands, and multiple coupled condensates appear, one condensate for each band, with each band having its own gap parameter. In contrast, in the graphene bilayer system 100, pairing is only possible between the different hole and electron bands, leading to a single condensate and a single gap parameter.

The combination of thin barriers, large interaction ratio rₛ, and matched electron and hole bands makes the graphene bilayer system 100 suitable for observing exciton superfluidity. The graphene bilayer system 100 permits study of the Fermi liquid to BCS superfluid phase transition in existing quality samples, with the possibility of superfluidity up to temperatures of 150 K. Unlike for high-temperature superconductors, the superfluidity can be maintained while the carrier density is swept over a wide range. By decreasing the carrier density at accessibly low temperatures, one could sweep from BCS superfluidity as far as the BCS-BEC crossover region.

Superfluidity will have applications in electronics, optics, electric field sensing, DC transformers, quantum integrated circuits, electrical interconnects, high frequency interconnects on integrated circuits, ultra-sensitive magnetic field sensing (mineral exploration, brain scanners), touch screen sensors, energy storage, and energy transmission. Further applications may include high speed data interconnects, high speed transistors, ultra-sensitive photon detectors for imaging over a wide range of wavelengths, DC transformers for small signals, and quantum bits for sensing and quantum information applications.

1. A small gap semiconductor system comprising:
two parallel semiconductor sheets formed of an atomically thin small gap semiconductor, one sheet containing electrons and the other containing holes;
a dielectric insulating barrier arranged parallel to and separating the two semiconductor sheets;
separate electrical contacts to each of the semiconductor sheets;
two dielectric layers above and below the two semiconductor sheets respectively; and
two conducting gates sandwiching the two semiconductor sheets and insulated from the respective semiconductor sheets by the respective dielectric layers.

2. The system according to claim 1, wherein the small gap semiconductor is bilayer graphene comprising two parallel, A-B stacked, closely coupled graphene sheets.

3. The system according to claim 2, wherein the separation between the layers in the A-B stacked bilayer graphene is 0.37 nanometres.

4. The system according to claim 2, wherein the width of the dielectric insulating barrier is substantially greater than the separation between the layers in the A-B stacked bilayer graphene.

5. The system according to claim 3, wherein the width of the dielectric insulating barrier is less than 10 nanometers.

6. The system according to claim 1, wherein the dielectric insulating barrier is hexagonal boron nitride.

7. The system according to claim 1, wherein the dielectric insulating barrier is a sheet formed of an insulating material selected from the group consisting of aluminum oxide, silicon oxide, and an organic insulator.
